(19) United States
(12) Patent Application Publication
(10) Pub. No.: US 2025/0179626 A1
(43) Pub. Date: Jun. 5, 2025

(54) THIN FILM MODIFICATION COMPOSITION, METHOD OF FORMING THIN FILM USING THIN FILM MODIFICATION COMPOSITION, SEMICONDUCTOR SUBSTRATE INCLUDING THIN FILM, AND SEMICONDUCTOR DEVICE INCLUDING SEMICONDUCTOR SUBSTRATE

(71) Applicant: SOULBRAIN CO., LTD., Gyeonggi-do (KR)

(72) Inventors: Chang Bong YEON, Gyeonggi-do (KR); Seung Hyun LEE, Gyeonggi-do (KR); Jae Sun JUNG, Gyeonggi-do (KR); Ji Hyun NAM, Gyeonggi-do (KR)

(21) Appl. No.: 18/843,486

(22) PCT Filed: Feb. 28, 2023
(86) PCT No.: PCT/KR2023/002766

§ 371 Date: Sep. 3, 2024

(30) Foreign Application Priority Data
Mar. 4, 2022 (KR) 10-2022-0028013
Oct. 28, 2022 (KR) 10-2022-0140808

(51) Int. Cl. C23C 16/02; C23C 16/455; H01L 21/02

(52) U.S. Cl. CPC C23C 16/0272; C23C 16/0236; C23C 16/45553; H01L 21/02304; H01L 21/02312

(57) ABSTRACT

The present invention relates to a thin film modification composition, a method of forming a thin film using the thin film modification composition, a semiconductor substrate including the thin film, and a semiconductor device including the semiconductor substrate. According to the present invention, by using a thin film modification composition consisting of a film growth/film quality improvement compound having a predetermined structure and a solvent with a specific dielectric constant, the growth rate of a deposition film may be appropriately reduced in a vacuum-based thin film process. Thus, even when forming a thin film on a substrate with a complex structure, step coverage and the thickness uniformity of a thin film may be greatly improved, the efficiency of etching a film may be improved, and impurity contamination may be significantly reduced.

### TECHNICAL FIELD

The present invention relates to a thin film modification composition, a method of forming a thin film using the thin film modification composition, a semiconductor substrate including the thin film, and a semiconductor device including the semiconductor substrate. More particularly, according to the present invention, by using a thin film modification composition consisting of a film growth/film quality improvement compound having a predetermined structure and a solvent with a specific dielectric constant, the growth rate of a deposition film may be appropriately reduced in a vacuum-based thin film process. Thus, even when forming a thin film on a substrate with a complex structure, step coverage and the thickness uniformity of a thin film may be improved, impurities may be greatly reduced, the efficiency of etching a film may be improved, and impurity contamination may be significantly reduced.

### BACKGROUND ART

As the integration of memory and non-memory semiconductor devices increases, the microstructure of a substrate is becoming increasingly complex.

For example, the ratio of the width to depth of the microstructure (hereinafter referred to as the ‘aspect ratio’) is increasing to 20:1 or more, and even to 100:1 or more. As the aspect ratio increases, it becomes difficult to form a deposition layer with a uniform thickness along the plane of the complex microstructure.

Accordingly, step coverage, which defines the thickness ratio of deposition layers formed at the top and bottom in the depth direction of the microstructure, remains at the level of 90%. Accordingly, the expression of the electrical properties of a device becomes increasingly difficult. Since a step coverage of 100% means that deposition layers formed on the upper and lower parts of the microstructure have the same thickness, it is necessary to develop a technology that can achieve step coverage close to 100%.

Thin films for semiconductors are made of nitride films, thin films, metal films, etc. Examples of nitride films include silicon nitride (SiN), titanium nitride (TiN), and tantalum nitride (TaN); examples of thin films include silicon oxide (SiO₂), hafnium oxide (HfO₂), and zirconium oxide (ZrO₂); and examples of metal films include molybdenum (Mo) and tungsten (W).

The thin film is generally used as a diffusion barrier between the silicon layer of a doped semiconductor and aluminum (Al), copper (Cu), etc., which are used as interlayer wiring materials. However, when depositing a tungsten (W) thin film on a substrate, the thin film is used as an adhesion layer.

In addition, as described above, to provide excellent and uniform physical properties to a thin film deposited on a substrate, it is essential that the thin film has high step coverage. Accordingly, the atomic layer deposition (ALD) process, which uses surface reactions, is used rather than the chemical vapor deposition (CVD) process, which mainly uses gaseous reactions. However, there are still problems in implementing 100% step coverage.

When increasing deposition temperature to achieve 100% step coverage, it is difficult to achieve step coverage. First, in a deposition process using a precursor and a reactant, an increase in the deposition temperature leads to a steep increase in the thin film growth rate (GPC). In addition, even when the ALD process is performed at 300° C. to alleviate the increase in GPC due to the increase in deposition temperature, the deposition temperature increases during the process. Accordingly, the problem still remains.

In addition, high-temperature processes are required to realize metal thin films with excellent film quality in semiconductor devices. A study has been reported in which the concentration of carbon and hydrogen remaining in a thin film was reduced by increasing the atomic layer deposition temperature to 400° C. (See the paper J. Vac. Sci. Technol. A, 35 (2017) 01B130).

However, as the deposition temperature increases, it becomes difficult to ensure step coverage. First, in a deposition process using a precursor and a reactant, an increase in deposition temperature may lead to a sharp increase in thin film growth rate (GPC). In addition, even when a known shielding agent is applied to reduce the increase in GPC with increasing deposition temperature, it is confirmed that GPC increases by about 10% at 300° C. That is, when deposition is performed at temperatures above 360° C., it is difficult to expect the GPC reduction effect provided by the conventionally known shielding agent.

Therefore, it is necessary to develop a method of forming a thin film that allows the formation of a thin film with a complex structure even at high temperatures, reduces the residual amount of impurities, and greatly improves step coverage and the thickness uniformity and electrical properties of a thin film; and a semiconductor substrate fabricated using the method.

### DISCLOSURE

### Technical Problem

Therefore, the present invention has been made in view of the above problems, and it is one object of the present invention to provide a thin film modification composition, a method of forming a thin film using the thin film modification composition, a semiconductor substrate including the thin film, and a semiconductor device including the semiconductor substrate. According to the present invention, by providing the thin film modification composition consisting of a film growth/film quality improvement compound having a predetermined structure and a solvent with a specific dielectric constant, the growth rate of a deposition film may be appropriately reduced in a vacuum-based thin film process. Thus, even when forming a thin film on a substrate with a complex structure, step coverage and the thickness uniformity of a thin film may be greatly improved, the efficiency of etching a film may be improved, and impurity contamination may be significantly reduced.

It is another object of the present invention to improve the density and dielectric properties of a thin film by improving the crystallinity and oxidation fraction of the thin film.

The above and other objects can be accomplished by the present invention described below.

### Technical Solution

In accordance with one aspect of the present invention, provided is a thin film modification composition including a liquid halogen compound having a vapor pressure of 1 torr (25° C.) or more; and a nonpolar solvent having a dielectric constant of 25 or less.

The thin film may be a vacuum-based deposition film or a vacuum-based etching film.

The liquid halogen compound may be an alkyl halide having 1 to 10 carbon atoms.

The liquid halogen compound may have a refractive index of 1.40 to 1.60, 1.40 to 1.58, or 1.40 to 1.56.

When the thin film is a deposition film, the liquid halogen compound may include compounds represented by Chemical Formulas 1-1 to 1-9 below.

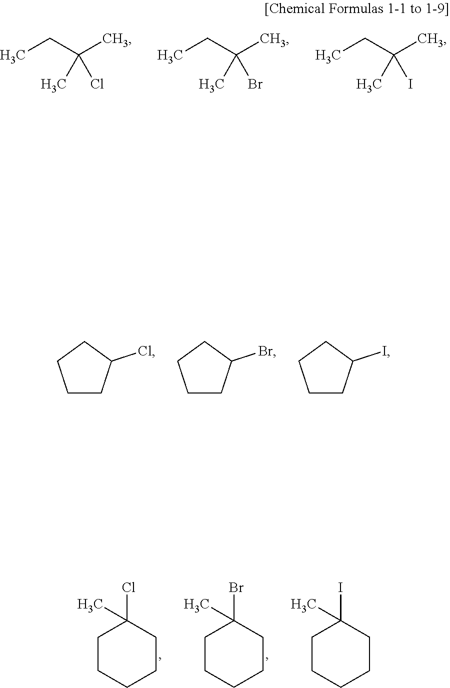

When the thin film is an etching film, the liquid halogen compound may include compounds represented by Chemical Formulas 2-1 to 2-3 below.

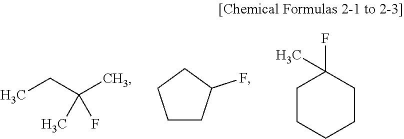

The liquid halogen compound may control a reaction surface of the above-described deposition film or etching film.

In the present invention, a nonpolar solvent having a dielectric constant of 25 or less may be used in combination with the liquid halogen compound.

For example, the dielectric constant may be 25 or less, as a specific example 15 or less, preferably 10 or less. Within this range, since the nonpolar solvent is not reactive with the above-described liquid halogen compound, the effects desired to be provided by the liquid halogen compound may be maximized without adversely affecting the process.

For example, the nonpolar solvent having a dielectric constant of 25 or less may be a hydrocarbon-based solvent, a halogen-based solvent, a solvent containing a heterocycle, or an alcohol-based solvent.

As a specific example, the nonpolar solvent having a dielectric constant of 25 or less may include one or more selected from an octane, 1,2-dichloroethane, dimethylethyl amine, tetrahydrofuran, N,N dimethylformamide, isobutyl alcohol, and ethyl alcohol.

In accordance with another aspect of the present invention, provided is a method of forming a thin film, the method including:
treating a surface of a substrate loaded into a chamber with the thin film modification composition; and
sequentially injecting a precursor compound and a reaction gas into the chamber and forming a vacuum-based deposition thin film on the substrate at 20 to 800° C. under a vacuum of less than 760 torr,
wherein the reaction gas is an oxidizing agent or a reducing agent.

The chamber may be an ALD chamber, a CVD chamber, a PEALD chamber, or a PECVD chamber.

The thin film modification composition and the precursor compound may be transferred into the chamber by a VFC method, a DLI method, or an LDS method.

At this time, a heating temperature of the deposition transfer line (hereinafter referred to as ‘injection line’) may be within a range of 25 to 200° C. on the substrate.

The thin film may be an oxide film or a nitride film.

The reaction gas may include O₂, O₃, N₂O, NO₂, H₂O, or O₂ plasma.

The thin film may be a thin film formed by laminating one or more metals selected from the group consisting of Al, Si, Ti, V, Co, Ni, Cu, Zn, Ga, Ge, Se, Zr, Nb, Mo, Ru, Rh, In, Sn, Sb, Te, Hf, Ta, W, Re, Os, Ir, La, Ce, and Nd in one or more layers.

The thin film may be used as a diffusion barrier film, an etching stop film, an electrode film, a dielectric film, a gate insulating film, a block thin film, or a charge trap.

In accordance with still another aspect of the present invention, provided is a method of forming a thin film, the method including:
forming a vacuum-based etching film on a substrate by injecting an etching material into a chamber,
wherein the etching material includes one or more selected from Cl₂, CCl₄, CF₂Cl₂, CF₃Cl, CF₄, CHF₃, C₂F₆, SF₆, BCl₃, Br₂, and CF₃Br.

The chamber may be an ALD chamber, a CVD chamber, a PEALD chamber, or a PECVD chamber.

The thin film modification composition and the precursor compound may be transferred into the chamber by a VFC method, a DLI method, or an LDS method.

The etching material may be mixed with Ar, H₂, or O₂ and used.

The method of forming a thin film using the thin film modification composition includes:
i) vaporizing the above-described thin film modification composition to form a modified area on a surface of a substrate loaded in a chamber; and
ii) performing 1st purging inside the chamber with a purge gas.

The thin film modification composition may be applied onto the substrate loaded into the chamber at 20 to 800° C.

The liquid halogen compound and nonpolar solvent constituting the thin film modification composition may be injected into the chamber separately or in a pre-mixed state.

In accordance with still another aspect of the present invention, provided is a method of forming a thin film, the method including:
i) vaporizing the above-described thin film modification composition to form a modified area on a surface of a substrate loaded in a chamber;
ii) performing 1st purging inside the chamber with a purge gas;
iii) vaporizing a precursor compound and adsorbing the precursor compound onto an area outside the modified area;
iv) performing 2nd purging inside the chamber with a purge gas;
v) supplying a reaction gas inside the chamber; and
vi) performing 3rd purging inside the chamber with a purge gas.

The thin film modification composition may be applied onto the substrate loaded into the chamber at 20 to 800° C.

The liquid halogen compound and nonpolar solvent constituting the thin film modification composition may be injected into the chamber separately or in a pre-mixed state.

The precursor compound may be a molecule composed of one or more selected from the group consisting of Al, Si, Ti, V, Co, Ni, Cu, Zn, Ga, Ge, Se, Zr, Nb, Mo, Ru, Rh, In, Sn, Sb, Te, Hf, Ta, W, Re, Os, Ir, La, Ce, and Nd, and may be a precursor having a vapor pressure of greater than 0.01 mTorr and 100 Torr or less at 25° C.

The thin film modification composition or the precursor compound may be vaporized, injected, and then subjected to plasma post-treatment.

In steps ii) and iv), an amount of the purge gas injected into the chamber at each step may be 10 to 100,000 times a volume of the introduced thin film modification composition or precursor compound.

The reaction gas may be an oxidizing agent or a reducing agent, and the reaction gas, the thin film modification composition, and the precursor compound may be transferred into the chamber by a VFC method, a DLI method, or an LDS method.

The substrate loaded into the chamber may be heated to 100 to 800° C., and the ratio of amount (mg/cycle) of the thin film modification composition and precursor compound fed into the chamber may be 1:1 to 1:20.

In accordance with still another aspect of the present invention, provided is a semiconductor substrate including the thin film formed using the above-described method of forming a thin film.

The thin film may have a multilayer structure of 2 or 3 layers.

In accordance with still another aspect of the present invention, provided is a semiconductor device including the above-described semiconductor substrate.

The semiconductor substrate may be low resistive metal gate interconnects, a high aspect ratio 3D metal-insulator-metal capacitor, a DRAM trench capacitor, 3D Gate-All-Around (GAA), or a 3D NAND flash memory.

### Advantageous Effects

The present invention has an effect of providing a thin film modification composition consisting of a film growth/film quality improvement compound having a predetermined structure and a solvent with a specific dielectric constant. According to the present invention, by using the thin film modification composition in a vacuum-based thin film process, the growth rate of a deposition film can be appropriately reduced in the vacuum-based thin film process. Thus, even when forming a thin film on a substrate with a complex structure, step coverage and the thickness uniformity of a thin film can be greatly improved, the efficiency of etching a film can be improved, and impurity contamination can be significantly reduced.

In addition, by more effectively reducing process by-products during thin film formation, corrosion or deterioration can be prevented, film quality can be improved, the crystallinity of a thin film can be improved, and the electrical properties of the thin film can be improved.

In addition, the present invention has an effect of providing a method of forming a thin film using the thin film modification composition and a semiconductor substrate including the thin film. According to the present invention, when forming a thin film, process by-products and reaction speed can be reduced, and the thin film growth rate can be appropriately reduced. Thus, even when forming a thin film on a substrate with a complex structure, step coverage and thin film density can be improved.

### DESCRIPTION OF DRAWINGS

FIGS. 1 to 3 are graphs showing the results of 1H NMR measurements performed to confirm the reactivity during synthesis and deposition of a thin film modification composition. FIG. 1 shows a thin film (top) obtained using only 2-chloro-2-methyl butane and a thin film (bottom) obtained using a 1:1 molar ratio mixture of 2-chloro-2-methyl butane and an octane, FIG. 2 shows a thin film (top) obtained using only iodocyclopentane and a thin film (bottom) obtained using a 1:1 molar ratio mixture of iodocyclopentane and 1,2-dichloroethane, and FIG. 3 shows a thin film (top) obtained using only 1-chloro-1-methyl cyclohexane and a thin film (bottom) obtained using a 1:1 molar ratio mixture of 1-chloro-1-methyl cyclohexane and an octane.

### BEST MODE

Hereinafter, a thin film modification composition of the present invention, a method of forming a thin film using the thin film modification composition, and a semiconductor substrate including the thin film will be described in detail.

In the present disclosure, unless otherwise specified, the term “thin film modification” refers to controlling a substrate surface that is used as a chemical reaction surface in a deposition process.

In the present disclosure, unless otherwise specified, the term “film growth/film quality improvement” means reducing, inhibiting, or blocking adsorption of precursor compounds for forming a thin film onto a substrate, and also reducing, inhibiting, or blocking adsorption of process by-products onto the substrate to improve thin film growth or film quality, such as electrical properties and thin film density.

In the present disclosure, the dielectric constant may be a value (calculated at 20° C.) known in the field to which the present invention belongs (see https://macro.lsu.edu/howto/solvents/Dielectric % 20Constant % 20.htm).

The present inventors confirmed that, by using a solvent with a specific dielectric constant and a film growth/film quality improvement compound with a predetermined structure as a thin film modification composition for modifying the surface of a substrate and improving the deposition or etching process in a vacuum-based deposition or etching process, the growth rate of a deposition film was appropriately reduced. Thus, even when forming a thin film on a substrate with a complex structure, step coverage and the thickness uniformity of a thin film were improved, and the efficiency of etching a film was improved. In particular, thin-thickness deposition was possible, and the remaining O, Si, metal, and metal oxides as process by-products and carbon residues, which were difficult to reduce in the past, were reduced. Based on these results, the present inventors conducted further studies on a film growth/film quality improvement compound to complete the present invention.

The target to which the thin film improvement composition of the present invention is applied may be a vacuum-based deposition film or a vacuum-based etching film.

For example, the deposition film or etching film may be provided with one or more precursors selected from the group consisting of Al, Si, Ti, V, Co, Ni, Cu, Zn, Ga, Ge, Se, Zr, Nb, Mo, Ru, Rh, In, Sn, Sb, Te, Hf, Ta, W, Re, Os, Ir, La, Ce, and Nd, and may provide a modified area for an oxide film, a nitride film, a metal film, or a selective thin film thereof. In this case, the effects desired in the present invention may be sufficiently achieved.

As a specific example, the thin film may have a film composition of silicon oxide or silicon nitride.

In addition to a commonly used diffusion barrier film, the thin film may be used in semiconductor devices as an etching stop film, an electrode film, a dielectric film, a gate insulating film, a block thin film, or a charge trap.

For example, as the precursor compound used in the formation of a thin film in the present invention, a compound represented by Chemical Formula 3 below may be used.

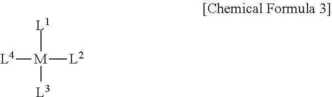

In Chemical Formula 3, M includes one or more selected from Al, Si, Ti, V, Co, Ni, Cu, Zn, Ga, Ge, Se, Zr, Nb, Mo, Ru, Rh, In, Sn, Sb, Te, Hf, Ta, W, Re, Os, Ir, La, Ce, and Nd; and L1, L2, L3, and L4 are —H, —X, —R, —OR, —NR₂, or Cp (cyclopentadiene) and are the same or different. Here, —X is F, Cl, Br, or I; —R is C₁-C₁₀ alkyl, C₁-C₁₀ alkene, or C₁-C₁₀ alkane and is linear or cyclic; and L1, L2, L3, and L4 are formed from 2 to 6 depending on an oxidation number of a central metal.

For example, when the central metal is divalent, L1 and L2 may be attached to the central metal as ligands. When the central metal is hexavalent, L1, L2, L3, L4, L5, and L6 may be attached to the central metal. The ligands corresponding to L1 to L6 may be the same or different.

M may be a trivalent metal, tetravalent metal, pentavalent metal, or hexavalent metal, preferably hafnium (Hf), zirconium (Zr), aluminum (Al), niobium (Nb), or tellurium (Ta). In this case, the effect of reducing process by-products and the effect of improving thin film density may be increased, and step coverage and the electrical properties, insulating properties, and dielectric properties of the thin film may be excellent.

L1, L2, L3, and L4 are —R, —X, or Cp, and may be the same or different. Here, —R may be C₁-C₁₀ alkyl, C₁-C₁₀ alkene, or C₁-C₁₀ alkane and may have a linear or cyclic structure.

In addition, L1, L2, L3, and L4 are —NR₂ or Cp, and may be the same or different. Here, —R may be H, C₁-C₁₀ alkyl, C₁-C₁₀ alkene, C₁-C₁₀ alkane, iPr, or tBu.

In addition, in Chemical Formula 3, L1, L2, L3, and L4 may be —H or —X, and may be the same or different. Here, —X may be F, Cl, Br, or I.

Specifically, examples of the aluminum precursor compound may include Al(CH₃)₃ and AlCl₄.

In addition, examples of the hafnium precursor compound may include tris(dimethylamido)cyclopentadienyl hafnium of CpHf(NMe₂)₃ and (methyl-3-cyclopentadienylpropylamino)bis(dimethylamino)hafnium of Cp(CH₂)₃NM₃Hf(NMe₂)₂.

In addition, examples of the silicon precursor compound may include hexachlorodisilane (HCDS), dichlorosilane (DCS), tris(dimethylamino)silane (3DMAS), bis(diethylamino)silane (BDEAS), and octamethylcyclotetrasiloxane (OMCTS).

The thin film modification composition of the present invention may control the growth of a vacuum-based thin film or control the film quality by reducing the speed of adsorption of a precursor compound on a substrate by controlling the surface of the substrate on which the precursor compound is adsorbed in advance.

The thin film modification composition may include a liquid halogen compound having a vapor pressure of 1 torr (25° C.) or more; and a nonpolar solvent having a dielectric constant of 25 or less. In this case, side reactions may be suppressed when forming a deposition film or etching film. In addition, by controlling the thin film growth rate, process by-products in a thin film may be reduced, corrosion or deterioration may be prevented, and the crystallinity of the thin film may be improved. In addition, even when a thin film is formed on a substrate having a complex structure, step coverage and the thickness uniformity of a thin film may be greatly improved, and impurity contamination may be minimized.

As a specific example, the halogen compound may have a refractive index of 1.40 to 1.60, 1.40 to 1.58, or 1.40 to 1.56. In this case, process by-products may be significantly reduced, step coverage may be excellent, thin film density may be improved, and the electrical properties of a thin film may be excellent.

The liquid halogen compound is preferably used in the atomic layer deposition (ALD) process. In this case, the surface of the substrate may be effectively protected without interfering with the adsorption of the precursor compound or the etching by the etching material, and process by-products may be effectively removed.

The liquid halogen compound may be preferably a liquid at room temperature (22° C.), and may have a density of 0.8 to 2.5 g/cm³ or 0.8 to 1.5 g/cm³ and a vapor pressure (20° C.) of 0.1 to 300 mmHg or 1 to 300 mmHg. Within this range, a modified area may be effectively formed, and the thickness uniformity of a thin film and film quality may be significantly improved.

More preferably, the liquid halogen compound may have a density of 0.75 to 2.0 g/cm³ or 0.8 to 1.3 g/cm³ and a vapor pressure (20° C.) of 1 to 260 mmHg. Within this range, a modified area may be effectively formed, and step coverage, the thickness uniformity of a thin film, and film quality may be improved.

The liquid halogen compound is preferably used in the atomic layer etching (ALE) process. In this case, since chemical etching is used, selective etching and isotropic etching characteristics of an etching film to be provided may be implemented.

The liquid halogen compound includes an alkyl halide having 1 to 10 carbon atoms. In this case, process by-products may be significantly reduced, step coverage may be excellent, thin film density may be improved, and the electrical properties of a thin film may be excellent.

The halogen contained in the alkyl halide may be fluorine, bromine, chlorine, or iodine, and at least one or more may be contained in the alkyl halide. In this case, process by-products may be significantly reduced, step coverage may be excellent, thin film density may be improved, and the electrical properties of a thin film may be excellent.

When the thin film is a deposition film, the liquid halogen compound may include preferably one or more selected from compounds represented by Chemical Formulas 1-1 to 1-9 below. In this case, by forming a deposition film, a relatively coarse thin film may be formed and side reactions may be suppressed. In addition, by controlling the thin film growth rate, process by-products within the thin film may be reduced, thereby reducing corrosion and deterioration. In addition, the crystallinity of a thin film may be improved. Thus, even when a thin film is formed on a substrate having a complex structure, step coverage and the thickness uniformity of a thin film may be greatly improved, and contamination by impurities may be minimized.

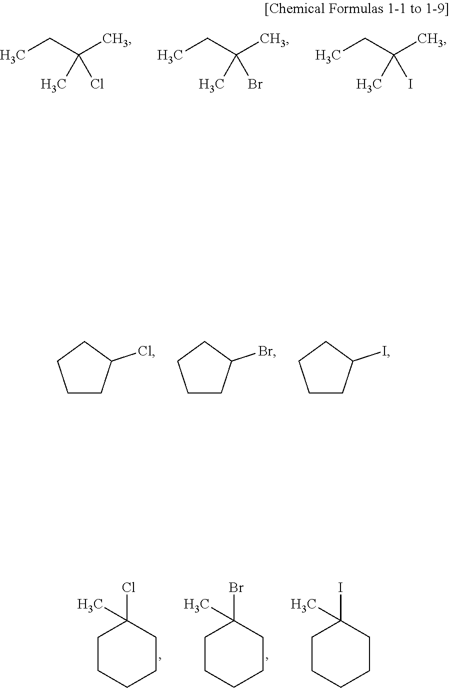

When the thin film is an etching film, the liquid halogen compound may preferably include compounds represented by Chemical Formulas 2-1 to 2-3 below. In this case, impurity contamination may be minimized and the etching process may be performed effectively.

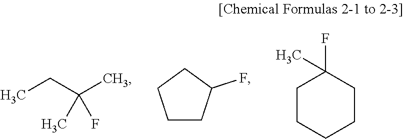

The above-described liquid halogen compound may be used alone, but considering the harsh atmosphere under vacuum, it is preferable to use the liquid halogen compound in combination with a specific organic solvent to perform the process efficiently.

At this time, using an organic solvent with a dielectric constant of 15 or less may improve the process without affecting the reaction mechanism of the liquid halogen compound under vacuum.

The nonpolar solvent having a dielectric constant of 25 or less may include a hydrocarbon-based solvent, a halogen-based solvent (excluding the liquid halogen compound), a solvent containing a heterocycle, or an alcohol-based solvent.

The hydrocarbon-based solvent may be a linear hydrocarbon compound having an alkyl group of 1 to 10 carbon atoms, such as, an octane (d: 1.9 at 25° C.).

The halogen-based solvent may be a linear hydrocarbon compound substituted with a terminal halogen. In this case, the compound may be substituted by one or more halogens, preferably two or more halogens. For example, 1,2-dichloroethane (d: 10.7 at 25° C.) may be used.

The solvent containing a heterocycle may include nitrogen or oxygen.

For example, the solvent containing nitrogen include dimethylethyl amine (d: 3.2 at 25° C.).

For example, the solvent containing oxygen include tetrahydrofuran (d: 7.6 at 25° C.).

For example, the alcohol-based solvent may include isobutyl alcohol (d: 16.68 at 25° C.) and ethyl alcohol (d: 24.55 at 25° C.).

As a specific example, the vacuum-based thin film modification composition may include one or more selected from the compounds represented by Chemical Formulas 1-1 to 1-9 and the nonpolar solvent having a dielectric constant of 25 or less. In this case, the growth rate of a deposition film may be efficiently controlled, process by-products may be significantly reduced, and step coverage and film quality may be improved. In addition, even when applied to a substrate having a complex structure, the uniformity of the thin film may be secured, and the step coverage may be greatly improved. In particular, deposition in a thin thickness is possible, and the remaining amounts of O, Si, metals, and metal oxides remaining as process by-products may be improved. In addition, even the remaining amount of carbon, which was difficult to reduce in the past, may be improved. In addition, film quality may be improved even when forming an etching film.

The reaction gas may include O₂, NH₃, or H₂.

The thin film may be a thin film formed by laminating one or more metals selected from the group consisting of Al, Si, Ti, V, Co, Ni, Cu, Zn, Ga, Ge, Se, Zr, Nb, Mo, Ru, Rh, In, Sn, Sb, Te, Hf, Ta, W, Re, Os, Ir, La, Ce, and Nd in one or more layers.

The thin film modification composition may provide a modified area for thin films.

The thin film modification composition does not remain on the thin film.

At this time, unless otherwise specified, non-residue refers to a case where the content of C element is less than 0.1 atom %, the content of Si element is less than 0.1 atom %, the content of N element is less than 0.1 atom %, and the content of halogen element is less than 0.1 atom % when analyzed by XPS. More preferably, in the secondary-ion mass spectrometry (SIMS) measurement method or X-ray photoelectron spectroscopy (XPS) measurement method, in which measurements are performed in the depth direction of a substrate, considering the increase/decrease rate of C, N, Si, and halogen impurities before and after using the thin film modification composition under the same deposition conditions, it is desirable that the increase/decrease rate of the signal sensitivity (intensity) of each element type does not exceed 5%.

For example, the thin film may include a halogen compound in an amount of 100 ppm or less.

The thin film may be used as a diffusion barrier film, an etching stop film, an electrode film, a dielectric film, a gate insulating film, a block thin film, or a charge trap, without being limited thereto.

The liquid halogen compound, the organic solvent, and the precursor compound may be preferably compounds having a purity of 99.9% or more, 99.95% or more, or 99.99% or more. For reference, when a compound having a purity of less than 99% is used, impurities may remain in a thin film or cause side reactions with precursors or reactants. Accordingly, it is desirable to use a material having a purity of 99% or more.

The method of forming a thin film according to the present invention may include a step of treating the surface of a substrate loaded into a chamber with the above-described thin film modification composition; and a step of sequentially injecting a precursor compound and a reaction gas into the chamber and forming a vacuum-based deposition thin film on the substrate at 20 to 800° C. under a vacuum of less than 760 torr. Here, the reaction gas may be an oxidizing agent or a reducing agent. In this case, the deposition rate of a thin film on a substrate may be reduced and the thin film growth rate may be appropriately reduced. Thus, even when forming a thin film on a substrate with a complex structure, step coverage and the thickness uniformity of a thin film may be greatly improved, and impurity contamination may be minimized.

In the step of treating with the thin film modification composition, the feeding time (sec) of the thin film modification composition on the surface of the substrate may be preferably 0.01 to 10 seconds, more preferably 0.02 to 8 seconds, still more preferably 0.04 to 6 seconds, still more preferably 0.05 to 5 seconds per cycle. Within this range, the thin film growth rate may be reduced, step coverage and economics may be excellent, and impurity contamination may be minimized.

In the present disclosure, the feeding time of the precursor compound is based on a flow rate of 0.1 to 500 mg/cycle at a chamber volume of 15 to 20 L, more specifically based on a flow rate of 0.8 to 200 mg/cycle at a chamber volume of 18 L.

The method of modifying a thin film according to the present invention may include step i) of vaporizing the above-described thin film modification composition to form a modified area on the surface of a substrate loaded in a chamber; and step ii) of performing 1st purging inside the chamber with a purge gas.

In addition, the method of modifying a thin film and the method of forming a thin film may include, as a preferred example, step i) of vaporizing the thin film modification composition and treating the surface of a substrate loaded into a chamber with the vaporized thin film modification composition; step ii) of performing 1st purging inside the chamber with a purge gas; step iii) of vaporizing a precursor compound and adsorbing the vaporized precursor compound onto the surface of the substrate loaded into the chamber; step iv) pf performing 2nd purging inside the chamber with a purge gas; step v) of supplying a reaction gas inside the chamber; and step vi) of performing 3rd purging inside the chamber with a purge gas.

At this time, steps i) to vi) may be repeated as a unit cycle until a thin film of the desired thickness is obtained. In this way, in one cycle, when the thin film modification composition of the present invention is injected before the precursor compound and is absorbed into the substrate, even when deposition is performed at high temperatures, the thin film growth rate may be appropriately reduced, process by-products may be effectively removed, the resistivity of the thin film may be reduced, and the step coverage may be significantly improved.

As another preferred example, the substrate may be manufactured by applying the thin film modification composition to a substrate loaded in a chamber at 20 to 800° C.

As a preferred example, in the method of forming a thin film according to the present invention, in one cycle, before introducing the precursor compound, the thin film modification composition of the present invention may be introduced to activate the surface of the substrate. Then, the precursor compound may be introduced and adsorbed onto the substrate. In this case, even when depositing a thin film at high temperatures, process by-products may be significantly reduced and step coverage may be significantly improved by appropriately reducing the thin film growth rate. In addition, the crystallinity of the thin film may be increased, thereby reducing the resistivity of the thin film. In addition, even when applied to semiconductor devices with a large aspect ratio, the thickness uniformity of the thin film may be greatly improved, thereby ensuring the reliability of the semiconductor device.

For example, in the method of forming a thin film, when the thin film modification composition is deposited before or after the deposition of the precursor compound, depending on the needs, the unit cycle may be repeated 1 to 99,999 times, preferably 10 to 10,000 times, more preferably 50 to 5,000 times, still more preferably 100 to 2,000 times. Within this range, the desired thickness of the thin film may be obtained, and the effects desired in the present invention may be sufficiently achieved.

The precursor compound is a compound having one or more selected from the group consisting of Al, Si, Ti, V, Co, Ni, Cu, Zn, Ga, Ge, Se, Zr, Nb, Mo, Ru, Rh, In, Sn, Sb, Te, Hf, Ta, W, Re, Os, Ir, La, Ce, and Nd as a central metal atom (M) and one or more ligands selected from C, N, O, H, X (halogen), and Cp (cyclopentadiene). For a precursor having a vapor pressure of 1 mTorr to 100 Torr at 25° C., despite natural oxidation, the effect of forming a modified area by the above-described thin film modification composition may be maximized.

For example, in the present invention, the chamber may be an ALD chamber, a CVD chamber, a PEALD chamber, or a PECVD chamber.

The thin film may be a silicon oxide film, a silicon nitride film, a titanium oxide film, a titanium nitride film, a hafnium oxide film, a hafnium nitride film, a zirconium oxide film, a zirconium nitride film, a tungsten oxide film, a tungsten nitride film, an aluminum oxide film, an aluminum nitride film, a niobium oxide film, a niobium nitride film, a tellurium oxide film, or a tellurium nitride film.

In the present invention, the liquid halogen compound or the precursor compound may be vaporized, injected, and then subjected to plasma post-treatment. In this case, the growth rate of a thin film may be improved and process by-products may be reduced.

When the thin film modification composition is first adsorbed on the substrate, the precursor compound is adsorbed, and then the precursor compound is adsorbed, the amount of purge gas injected into the chamber in the step of purging the unadsorbed thin film modifier or thin film modification composition is not particularly limited as long as the amount of purge gas is sufficient to remove the unadsorbed thin film modification composition. For example, the amount of purge gas may be 10 to 100,000 times, preferably 50 to 50,000 times, more preferably 100 to 10,000 times. Within this range, by effectively removing the unadsorbed thin film modification composition, a thin film may be formed evenly and deterioration of film quality may be prevented. Here, the input amounts of the purge gas and thin film modification composition are each based on one cycle, and the volume of the thin film modification composition refers to the volume of the vaporized thin film modification composition, or a volume of a vaporized liquid halogen compound and nonpolar solvent.

As a specific example, when the thin film modification composition is injected at a flow rate of 200 sccm, and when the purge gas is injected at a flow rate of 5000 sccm in the step of purging the unadsorbed thin film modification composition, the amount of the injected purge gas is 25 times the amount of the injected thin film modification composition.

In addition, in the step of purging the unadsorbed precursor compound, the amount of purge gas injected into the chamber is not particularly limited as long as the amount is sufficient to remove the unadsorbed precursor compound. For example, the amount may be 10 to 10,000 times, preferably 50 to 50,000 times, more preferably 100 to 10,000 times the volume of the precursor compound injected into the chamber. Within this range, by sufficiently removing the unadsorbed precursor compound, a thin film may be formed evenly and deterioration of film quality may be prevented. Here, the input amounts of the purge gas and precursor compound are each based on one cycle, and the volume of the precursor compound refers to the volume of the vaporized precursor compound.

In addition, in the purging step performed immediately after the reaction gas supply step, the amount of purge gas injected into the chamber may be 10 to 10,000 times, preferably 50 to 50,000 times, more preferably 100 to 10,000 times the volume of reaction gas injected into the chamber. Within this range, the desired effects may be sufficiently achieved. Here, the input amounts of purge gas and reaction gas are based on one cycle.

The thin film modification composition and precursor compound may be transferred into the chamber preferably by a VFC method, a DLI method, or an LDS method, more preferably by an LDS method.

The liquid halogen compound and nonpolar solvent constituting the thin film modification composition may be transported separately into the chamber, or may be transported together in a mixed state.

For example, the substrate loaded into the chamber may be heated to 100 to 650° C., as a specific example, 150 to 550° C. The thin film modification composition or the precursor compound may be injected onto the substrate in an unheated or heated state, or may be injected unheated and then heated during the deposition process, depending on the deposition efficiency. For example, the thin film modification composition or the precursor compound may be injected onto the substrate at 100 to 650° C. for 1 to 20 seconds.

The ratio of amount (mg/cycle) of the precursor compound and thin film modification composition fed into the chamber may be preferably 1:1.5 to 1:20, more preferably 1:2 to 1:15, still more preferably 1:2 to 1:12, still more preferably 1:2.5 to 1:10. Within this range, step coverage may be improved, and process by-products may be significantly reduced.

For example, in the method of forming a thin film, when the thin film modification composition and the precursor compound are used, the deposition rate reduction rate expressed by Equation 1 below may be 20% or more, preferably 50% or more. In this case, by using the film growth/film quality improvement compound or thin film modification composition having the above-described structure, a relatively coarse thin film may be formed, and the growth rate of a thin film may be significantly reduced. Thus, even when applied to a substrate having a complex structure at high temperatures, the uniformity of a thin film may be secured, and step coverage may be greatly improved. In addition, deposition in a thin thickness is possible, the remaining amounts of O, Si, metals, and metal oxides remaining as process by-products may be improved. In addition, even the remaining amount of carbon, which was difficult to reduce in the past, may be improved.

$$Deposition rate reduction rate = [ \{ ( {DR}_{i} ) - ( {DR}_{f} ) \} / ( {DR}_{i} ) ] \times 100 \qquad [ Equation 1 ]$$

In Equation 1, deposition rate (DR, Å/cycle) is the speed at which a thin film is deposited. In the deposition of a thin film formed from a precursor and a reactant, DRᵢ (initial deposition rate) is the deposition rate of a thin film formed without adding a thin film modification composition, and DR_{f} (final deposition rate) is the deposition rate of a thin film formed by adding the thin film modification composition during the above process. Here, the deposition rate (DR) is measured at room temperature and pressure using an ellipsometer for a thin film with a thickness of 3 to 30 nm, and the unit is Å/cycle.

In Equation 1, the thin film growth rate per cycle, when using and not using the thin film modification composition, refers to a thin film deposition thickness (Å/cycle) per cycle, i.e., a deposition rate. For example, when measuring the deposition rate, an ellipsometer is used to measure the final thickness of a thin film having a thickness of 3 to 30 nm at room temperature under normal pressure, and then an average deposition rate is calculated by dividing the measured thickness value by the total number of cycles.

In Equation 1, “when the thin film modification composition is not used” means that a thin film is manufactured by adsorbing only a precursor compound on the substrate in the thin film deposition process. As a specific example, the case refers to a case where a thin film is formed by omitting the step of adsorbing the thin film modification composition and the step of purging the unadsorbed thin film modification composition in the method of forming a thin film.

In the method of forming a thin film, the residual halogen intensity (c/s) in the thin film may be preferably 100,000 or less, more preferably 70,000 or less, still more preferably 50,000 or less, still more preferably 10,000 or less, as a preferred example, 5,000 or less, still more preferably 1,000 to 4,000, still more preferably 1,000 to 3,800 as measured using a thin film having a thickness (Å/cycle) of 100 according to SIMS. Within this range, corrosion and deterioration may be effectively prevented.

In the present disclosure, purging may be performed at preferably 1,000 to 50,000 sccm (standard cubic centimeter per minute), more preferably 2,000 to 30,000 sccm, still more preferably 2,500 to 15,000 sccm. Within this range, the thin film growth rate per cycle may be appropriately controlled. In addition, since deposition is performed as an atomic mono-layer or nearly an atomic mono-layer, the film quality may be improved.

The atomic layer deposition (ALD) process is very advantageous in manufacturing integrated circuits (ICs) that require a high aspect ratio. In particular, the ALD process has advantages such as excellent conformality, uniformity, and precise thickness control due to the self-limiting thin film growth mechanism.

For example, the method of forming a thin film may be performed at a deposition temperature of 50 to 800° C., preferably 300 to 700° C., more preferably 400 to 650° C., still more preferably 400 to 600° C., still more preferably 450 to 600° C. Within this range, a thin film with excellent film quality may be grown while implementing ALD process characteristics.

For example, the method of forming a thin film may be performed at a deposition pressure of 0.01 to 20 Torr, preferably 0.1 to 20 Torr, more preferably 0.1 to 10 Torr, most preferably 0.3 to 7 Torr. Within this range, a thin film having a uniform thickness may be obtained.

In the present disclosure, the deposition temperature and the deposition pressure may be measured as temperature and pressure formed within the deposition chamber, or as temperature and pressure applied to the substrate within the deposition chamber.

The method of forming a thin film may preferably include a step of increasing the temperature inside the chamber to the deposition temperature before introducing the precursor compound into the chamber; and/or a step of purging by injecting an inert gas into the chamber before introducing the precursor compound into the chamber.

In addition, as a thin film manufacturing device capable of implementing the thin film manufacturing method, the present invention may include a thin film manufacturing device including an ALD chamber, a first vaporizer for vaporizing a precursor compound, a first transport means for transporting the vaporized precursor compound into the ALD chamber, a second vaporizer for vaporizing a thin film precursor, and a second transport means for transporting the vaporized thin film precursor into the ALD chamber. Here, vaporizers and transport means commonly used in the technical field to which the present invention pertains may be used in the present invention without particular limitation.

The heating temperature of the deposition transport means (hereinafter referred to as ‘injection line’) may be in the range of 25 to 200° C. on the substrate, and the reaction gas may include O₂, O₃, N₂O, NO₂, H₂O, or O₂ plasma.

According to another aspect of the present invention, the present invention may provide a method of forming a thin film, the method including a step of treating the surface of a substrate loaded into a chamber with the above-described thin film modification composition; and a step of forming a vacuum-based etching film on the substrate by injecting an etching material into the chamber. Here, the etching material includes one or more selected from Cl₂, CCl₄, CF₂Cl₂, CF₃Cl, CF₄, CHF₃, C₂F₆, SF₆, BCl₃, Br₂, and CF₃Br.

The etching material may be mixed with Ar, H₂, or O₂ and used, and except for this, the deposition film formation process is the same, so repeated descriptions are omitted.

In addition, the present invention provides a semiconductor substrate, and the semiconductor substrate is fabricated by the thin film formation method. In this case, the step coverage and thickness uniformity of a thin film may be excellent, and the density and electrical properties thereof may be excellent.

For example, the thin film may have a thickness of 0.1 to 20 nm, preferably 0.5 to 20 nm, more preferably 1.5 to 15 nm, still more preferably 2 to 10 nm. Within this range, thin film properties may be excellent.

The thin film may have a carbon impurity content of preferably 5,000 counts/sec or less or 1 to 3,000 counts/sec, still more preferably 10 to 1,000 counts/sec, still more preferably 50 to 500 counts/sec. Within this range, thin film properties may be excellent, and thin film growth rate may be reduced.

For example, the thin film may have a step coverage of 90% or more, preferably 92% or more, more preferably 95% or more. Within this range, since even a thin film of complex structure may be easily deposited on a substrate, the thin film may be applied to next-generation semiconductor devices.

The manufactured thin film may have a thickness of preferably 20 nm or less, a dielectric constant of 5 to 29 based on a thin film thickness of 10 nm, a carbon, nitrogen, and halogen content of 5,000 counts/sec or less, and a step coverage of 90% or more. Within this range, the thin film may have excellent performance as a dielectric film or blocking film, without being limited thereto.

For example, when necessary, the thin film may have a multilayer structure of two or three layers. As a specific example, the multilayer film with a two-layer structure may have a lower layer-middle layer structure, and the multilayer film with a three-layer structure may have a lower layer-middle layer-upper layer structure.

For example, the lower layer may be formed of one or more selected from the group consisting of Si, SiO₂, MgO, Al₂O₃, CaO, ZrSiO₄, ZrO₂, HfSiO₄, Y₂O₃, HfO₂, LaLuO₂, Si₃N₄, SrO, La₂O₃, Ta₂O₅, BaO, and TiO₂.

For example, the middle layer may be formed of TiₓN_{y}, preferably TN.

For example, the upper layer may be formed of one or more selected from the group consisting of W and Mo.

The semiconductor substrate may be low resistive metal gate interconnects, a high aspect ratio 3D metal-insulator-metal capacitor, a DRAM trench capacitor, 3D Gate-All-Around (GAA), or a 3D NAND flash memory.

Hereinafter, preferred examples and drawings are presented to help understand the present invention, but the following examples and drawings are only illustrative of the present invention, and it is obvious to those skilled in the art that various changes and modifications are possible within the scope and technical idea of the present invention. Such changes and modifications fall within the scope of the appended patent claims.

### EXAMPLES

### Test Example 1

### Examples 1 to 4, Comparative Example 1, Reference Examples 1 and 2

For the experiment, among solvents with a dielectric constant of 15 or less, a compound (d: 1.9 at 25° C.) represented by Chemical Formula 4-1 below, a compound (d: 3.2 at 25° C.) represented by Chemical Formula 4-2 below, a compound (d: 7.6 at 25° C.) represented by Chemical Formula 4-3 below, a compound (d: 10.7 at 25° C.) represented by Chemical Formula 4-4 below, a compound (d: 16.7 at 25° C.) represented by Chemical Formula 4-5 below, a compound (d: 24.6 at 25° C.) represented by Chemical Formula 4-6 below, and a compound (d: 36.7 at 25° C.) represented by Chemical Formula 4-7 below were each mixed with the compounds represented by Chemical Formulas 1-1, 1-4, and 1-7 in a mole ratio of 1:1, and the degree of reactivity was confirmed by checking for new impurity peaks through ¹H-NMR.

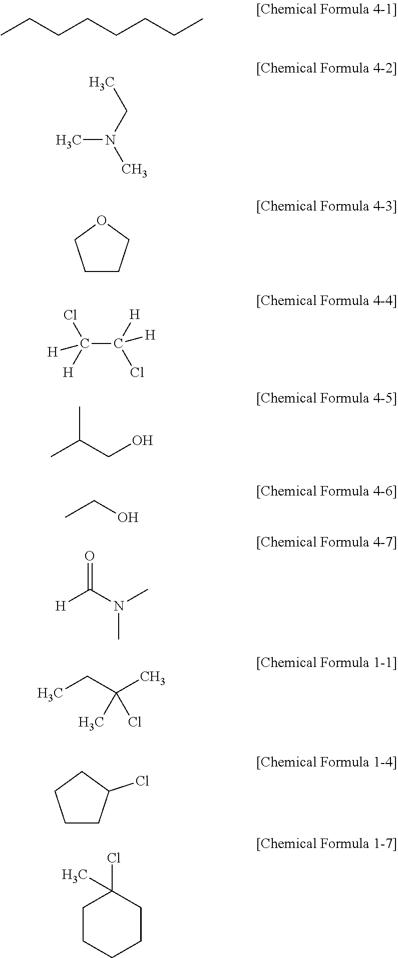

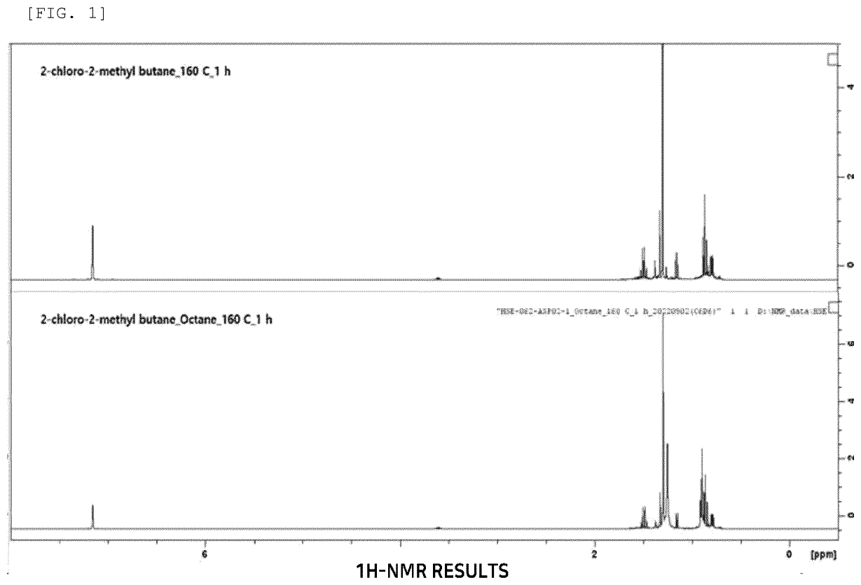

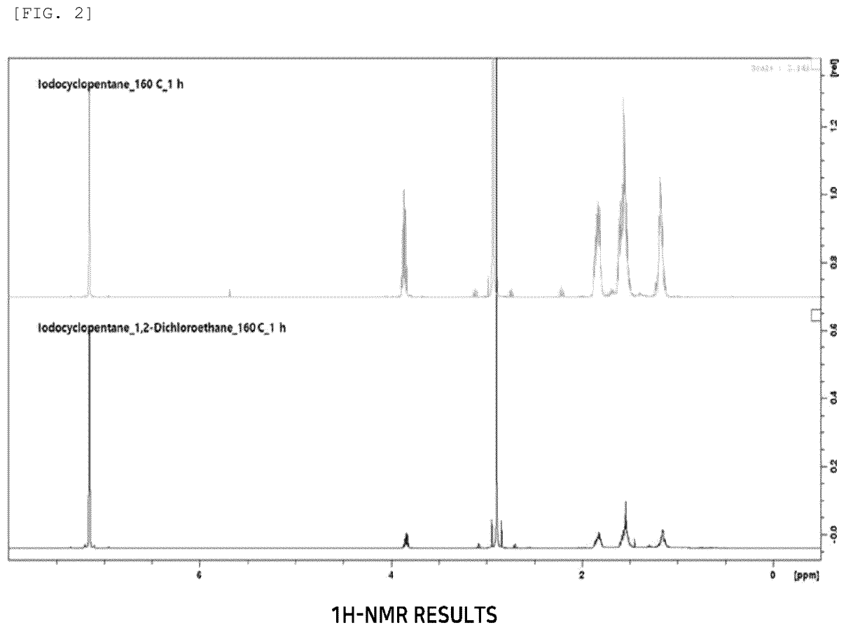

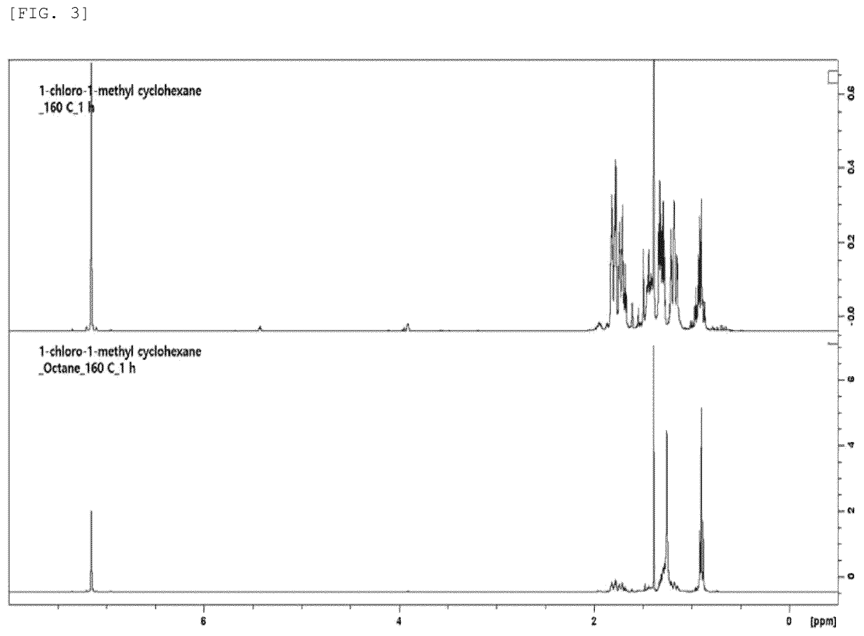

*The results obtained are summarized in Table 1 and FIGS. 1 to 3 below. Here, when a new impurity peak was observed, it was considered to be reactive and marked as O, and when a new impurity peak was not observed, it was considered to be non-reactive and marked as X.

TABLE 1

| Liquid halogen | | | |
|---|---|---|---|
| compound | Chemical | Chemical | Chemical |
| nonpolar solvent | Formula 1-1 | Formula 1-4 | Formula 1-7 |
| Chemical Formula 4-1 | X | X | X |
| (Example 1) | | | |
| Chemical Formula 4-2 | X | X | X |
| (Example 2) | | | |
| Chemical Formula 4-3 | X | X | X |
| (Example 3) | | | |
| Chemical Formula 4-4 | X | X | X |
| (Example 4) | | | |
| Chemical Formula 4-5 | ◯ | ◯ | X |
| (Reference Example 1) | | | |
| Chemical Formula 4-6 | ◯ | ◯ | X |
| (Reference Example 2) | | | |
| Chemical Formula 4-7 | ◯ | ◯ | ◯ |
| (Comparative Example | | | |
| 1) | | | |

As shown in Table 1 and FIGS. 1 to 3 below, in the case of Examples 1 to 4 in which the compounds represented by Chemical Formulas 4-1, 4-2, 4-3, and 4-4 with a dielectric constant of 15 or less were mixed, no reactivity was observed regardless of the type of liquid halogen compound. It was judged that such a case would effectively improve the deposition process. On the other hand, in the case of Reference Example 1 in which the compound represented by Chemical Formula 4-5 with a dielectric constant slightly exceeding 15 was mixed, in the case of iodocyclopentane, it was observed to have no reactivity, and from this result, it was judged to be appropriate for improving the deposition process depending on the type of liquid halogen compound.

In addition, in the case of Reference Example 2 in which the compound represented by Chemical Formula 4-6 with a dielectric constant slightly exceeding 15 was mixed, in the case of iodocyclopentane, it was observed to have no reactivity, and from this result, it was judged to be appropriate for improving the deposition process depending on the type of liquid halogen compound.

On the other hand, in the case of Comparative Example 1 in which the compound represented by Chemical Formula 4-7 with a dielectric constant exceeding 25 was mixed, it was observed to have reactivity regardless of the type of liquid halogen compound, and accordingly was judged not to be suitable for improving the deposition process.

### Test Example 2

The ALD deposition process was performed using the components and processes shown in Table 1.

Specifically, as shown in Table 1 below, in Comparative Example 1-1, a hexachlorodisilane (HCDS) precursor was used for SiN deposition. The canister heating temperature was 35° C., the N₂ carrier was injected at a flow rate of 40 sccm for 3 seconds, NH₃ was injected at a flow rate of 1000 sccm for 30 seconds, N₂ purge was injected at a flow rate of 1000 sccm for 12 seconds, and the cycle was repeated 100 to 150 times.

At this time, the canister heating temperature was 50° C., and the N₂ carrier was injected at a flow rate of 100 sccm for 3 seconds. In addition, the compounds represented by Chemical Formulas 1-1, 1-4, and 1-7 were injected separately for 3 seconds, and the cycle was repeated 100 to 150 times.

Specifically, each of the compounds represented by Chemical Formulas 1-1, 1-4, and 1-7 was mixed at a 1:1 mole ratio among the organic solvents represented by Chemical Formulas 4-1 to 4-6 below according to the compositions shown in Table 1, and a liquid delivery system (LDS) was used.

For the thin films obtained in Examples 1 to 4, Comparative Example 1, and Reference Examples 1 and 2, the thickness of a 10 nm SiN thin film was analyzed through ellipsometry optical analysis.

In addition, for the thin films obtained in Examples 1 to 4, Comparative Example 1, and Reference Examples 1 and 2, the thickness of an SiN thin film deposited at 10 nm thickness was measured through ellipsometry optical analysis fitting, and the measured thickness was divided by a total ALD cycle to measure the deposition rate (Å/cycle) of thickness per cycle.

As a result, compared to Comparative Example 1, in the case of Examples 1 to 4, it was confirmed that the deposition rate was reduced by 20 or more. On the other hand, in the case of Reference Examples 1 and 2, it was confirmed that the deposition rate was reduced by 20 or more only when the compound represented by Chemical Formula 1-7 was used.

1. A thin film modification composition, comprising:
a liquid halogen compound having a vapor pressure of 1 torr (25° C.) or more; and
a nonpolar solvent having a dielectric constant of 25 or less.

2. The thin film modification composition according to claim 1, wherein the liquid halogen compound is an alkyl halide having 1 to 10 carbon atoms.

3. The thin film modification composition according to claim 1, wherein the liquid halogen compound has a refractive index of 1.40 to 1.60.

4. The thin film modification composition according to claim 1, wherein, when the thin film is a deposition film, the liquid halogen compound comprises compounds represented by Chemical Formulas 1-1 to 1-9 below; and when the thin film is an etching film, the liquid halogen compound comprises compounds represented by Chemical Formulas 2-1 to 2-3 below.

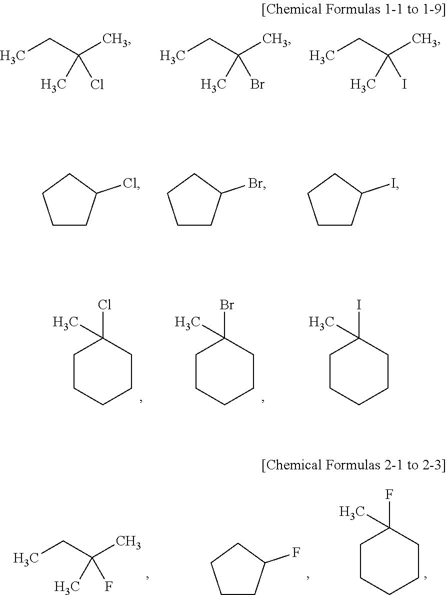

5. The thin film modification composition according to claim 1, wherein the nonpolar solvent having a dielectric constant of 25 or less is a hydrocarbon-based solvent, a halogen-based solvent, a solvent containing a heterocycle, or an alcohol-based solvent.

6. The thin film modification composition according to claim 5, wherein the nonpolar solvent having a dielectric constant of 25 or less comprises one or more selected from an octane, 1,2-dichloroethane, dimethylethyl amine, tetrahydrofuran, N,N dimethylformamide, isobutyl alcohol, and ethyl alcohol.

7. A method of forming a thin film, comprising:
treating a surface of a substrate loaded into a chamber with the thin film modification composition according to claim 1; and
sequentially injecting a precursor compound and a reaction gas into the chamber and forming a vacuum-based deposition thin film on the substrate at 20 to 800° C. under a vacuum of less than 760 torr,
wherein the reaction gas is an oxidizing agent or a reducing agent.

8. A method of forming a thin film, comprising:
treating a surface of a substrate loaded into a chamber with the thin film modification composition according to claim 1; and
forming a vacuum-based etching film on the substrate by injecting an etching material into the chamber,
wherein the etching material comprises one or more selected from Cl₂, CCl₄, CF₂Cl₂, CF₃Cl, CF₄, CHF₃, C₂F₆, SF₆, BCl₃, Br₂, and CF₃Br.

9. The method according to claim 7, wherein the chamber is an ALD chamber, a CVD chamber, a PEALD chamber, or a PECVD chamber.

10. The method according to claim 9, wherein the thin film modification composition and the precursor compound are transferred into the chamber by a VFC method, a DLI method, or an LDS method, and a heating temperature of the injection line is 25 to 200° C. on the substrate.

11. The method according to claim 8, wherein the etching material is mixed with Ar, H₂, or O₂ and used.

12. A semiconductor substrate, comprising the thin film manufactured using the method according to claim 7.

13. The semiconductor substrate according to claim 12, wherein the thin film has a multilayer structure of 2 or 3 layers.

14. A semiconductor device, comprising the semiconductor substrate according to claim 12.
